(19) United States
(12) Patent Application Publication
(10) Pub. No.: US 2007/0257258 A1
(43) Pub. Date: Nov. 8, 2007

(54) Semiconductor evaluation device and evaluation method using the same

(76) Inventors: Daisaku Ikoma, Osaka (JP); Katsuhiro Ootani, Nara (JP)

Correspondence Address: MCDERMOTT WILL & EMERY LLP, 600 13TH STREET, NW, WASHINGTON, DC, 20005-3096, US

(21) Appl. No.: 11/653,328

(22) Filed: Jan. 16, 2007

(30) Foreign Application Priority Data
May 8, 2006 (JP) 2006-129073

(51) Int. Cl. H01L 23/58; H01L 29/10

(52) U.S. Cl. 257/48

(57) ABSTRACT

A semiconductor evaluation device evaluates an amount of mask misalignment in an optical exposure step during the fabrication of a semiconductor device. The semiconductor evaluation device has a first semiconductor region selectively formed in a semiconductor substrate, a first gate electrode having a cross-shaped plan configuration, formed on the first semiconductor region with a first gate insulating film interposed therebetween, and an intersecting portion at which a first gate portion disposed in an X-axis direction and a second gate portion disposed in a Y-axis direction intersect each other, and a first impurity diffusion layer formed in the area of the first semiconductor region which is other than the portion thereof underlying the first gate electrode and partitioned by the first gate electrode into four diffusion regions.

### CROSS-REFERENCE TO RELATED APPLICATIONS

The teachings of Japanese Patent Application JP 2006-129073, filed May 8, 2006, are entirely incorporated herein by reference, inclusive of the claims, specification, and drawings.

### BACKGROUND OF THE INVENTION

The present invention relates to a semiconductor evaluation device for electrically evaluating an amount of mask misalignment or displacement in the process steps for fabricating a semiconductor device and to an evaluation method using the same.

As large scale integrated circuits (LSIs) have become higher in performance and integration in recent years, the sizes of patterns for elements formed on semiconductor substrates and line-to-line spacings have become increasingly smaller and narrower. These miniaturized patterns are transferred onto the semiconductor substrates by using a plurality of masks in a lithographic step. However, the use of the plurality of masks causes mask misalignment or displacement between individual mask layers. When the amount of mask misalignment is larger than a standard value, a short circuit or an open defect occurs to cause a reduction in fabrication yield and the like. Even when the amount of mask misalignment is no more than the standard value, it serves as a factor which varies transistor characteristics and causes defective circuit characteristics and the like. In particular, it is important in the design of a static random access memory (SRAM) to recognize a precise amount of mask misalignment and provide the SRAM with a margin for variations in the characteristics of transistors in SRAM cells due to the mask misalignment. This is because each of SRAM manufacturers has minimized a pattern area (cell area) for one item of data in a SRAM to be more cost-competitive on the market and variations in the characteristics of the transistors in the SRAM cells cause defective characteristics.

Conventionally, mask misalignment has been evaluated by adopting an optical method using a misalignment evaluation pattern having a planar pattern of a quadrilateral plan configuration or the like which is disposed at a corner portion of a semiconductor chip or the like. When one lot contains twenty-five wafers, e.g., the conventional method has normally performed spotwise evaluation with respect to only one wafer to be processed first without evaluating all the wafers, thereby reducing evaluation cost. In the conventional optical method for evaluating misalignment, however, evaluation can be performed only immediately after a masking step to be evaluated and, if the target masking step is passed over and the timing is missed, evaluation cannot be performed any more afterwards. Therefore, when a wafer has a large number of defects and the cause of the defects is to be analyzed, it is impossible to analyze whether or not the defects are attributable to misalignment. Moreover, because the conventional misalignment evaluation pattern is disposed at each of the four corner portions of a semiconductor chip, it is impossible to evaluate misalignment which has occurred in an inner portion of the chip.

To solve the problems encountered by the optical method for evaluating misalignment, i.e., the problems that analysis cannot be performed afterwards and that a semiconductor chip cannot be evaluated at an arbitrary position on a semiconductor chip, there have been proposed several methods which electrically evaluate an amount of misalignment. These methods primarily evaluate misalignment between a diffusion layer and a contact, misalignment between a gate electrode and a contact, or misalignment between a metal wire and a via. There have been few reports on methods for electrically evaluating an amount of misalignment between a diffusion layer and a gate electrode which greatly affects the characteristics of transistors.

An example of the methods for electrically evaluating an amount of misalignment between a diffusion layer and a gate electrode has been reported by IEEE Trans. on Semiconductor Manufacturing, Vol. 15, pp. 108-117, (2000) (hereinafter referred to as Document 1). The measurement accuracy reported in Document 1 is 6.5 nm with 3σ (σ is a standard deviation), which cannot be said to be sufficient when consideration is given to the fact that the measurement accuracy achieved by an optical method is about 3 nm with 3σ. To evaluate an amount of vertical misalignment and an amount of horizontal misalignment, it has been conventionally necessary to individually prepare an evaluation pattern for vertical misalignment and an evaluation pattern for horizontal misalignment. When the layouts of the evaluation patterns are different in different directions, the electric characteristics of elements to be evaluated may be undesirably different. Accordingly, it is desirable to allow simultaneous measurement in the vertical and horizontal directions by using a single evaluation pattern.

A misalignment evaluation pattern which allows electrical measurement is placed in a scribe lane on a wafer or the like together with a group of test elements termed “Test Element Group (TEG)” and used for the purposes of defect analysis, monitoring a fabrication process, and improving the degrees of perfection of a fabrication technology and design. Since the measurement of electric characteristics is performed by using the switching function of a tester or on-chip circuits, an advantage of a shorter evaluation time than in the optical method is also offered.

As described above, electrical evaluation of an amount of misalignment between a diffusion layer and a gate electrode is important in terms of improving the production yield of a semiconductor device. However, the conventional electric evaluation method has the problems that the measurement accuracy is insufficient and that vertical misalignment and horizontal misalignment cannot be evaluated by using the same pattern.

### SUMMARY OF THE INVENTION

The present invention aims at solving the conventional problems described above and an object of the present invention is to allow electrical measurement of an amount of misalignment between a diffused layer and a gate electrode and thereby allow high-accuracy and prompt evaluation.

To attain the object, the present invention adopts a structure which uses, as a gate electrode pattern, the same pattern in either of the vertical and horizontal directions, i.e., a gate electrode having a cross-shaped plan configuration.

Specifically, a semiconductor evaluation device according to the present invention is a semiconductor evaluation device for evaluating an amount of mask misalignment in an optical exposure step during fabrication of a semiconductor device, the device comprising: a first semiconductor region selectively formed in a semiconductor substrate; a first gate electrode having a cross-shaped plan configuration, formed on the first semiconductor region with a first gate insulating film interposed therebetween, and having an intersecting portion at which a first gate portion disposed in an X-axis direction and a second gate portion disposed in a Y-axis direction intersect each other; and a first impurity diffusion layer formed in an area of the first semiconductor region which is other than a portion thereof underlying the first gate electrode and partitioned by the first gate electrode into four diffusion regions.

In the semiconductor evaluation pattern according to the present invention, when the first gate electrode is displaced in, e.g., the Y-axis direction, each of the two pairs of MISFETs (Metal Insulator Semiconductor Field Effect Transistors) using the four diffusion regions which are adjacent to each other in the Y-axis direction have different gate widths. The amount of mask misalignment can be evaluated from the correlation between the amount of displacing the first gate electrode and the differences between the electric characteristics of the two pairs of transistors having the different gate widths. This allows prompt and high-accuracy evaluation of vertical misalignment and horizontal misalignment at an arbitrary position on a wafer or chip by using the same pattern.

It is to be noted that the plan configuration of the first impurity diffusion layer is not important provided that four transistors are formed by using the first gate electrode having the cross-shaped plan configuration.

The difference between the electric characteristics is not limited to that between the MISFETS using one pair of diffusion layers in the cross-shaped gate electrode but may be that between MISFETs formed by using different cross-shaped gate electrodes.

The transistors may be either N-channel MISFETs using electrons as carriers or P-channel MISFETs using holes as carriers.

Preferably, the semiconductor evaluation device according to the present invention further comprises: a plurality of measurement pads formed outside the semiconductor region and electrically connected to the individual diffusion regions of the first impurity diffusion layer each via a contact and a wire.

In the semiconductor evaluation device according to the present invention, the two of the diffusion regions of the first impurity diffusion layer which are adjacent to each other with the first gate portion interposed therebetween and located on a positive side of the Y-axis are preferably connected to a source terminal and the two of the diffusion regions of the first impurity diffusion layer which are adjacent to each other with the first gate portion interposed therebetween and located on a negative side of the Y-axis are preferably connected to a drain terminal.

In the semiconductor evaluation device according to the present invention, the intersecting portion of the first gate electrode preferably has a center position thereof displaced from a center position of the first semiconductor region.

Preferably, the semiconductor evaluation device according to the present invention further comprises: a second semiconductor region formed on the semiconductor substrate, isolated from the first semiconductor region by an isolation region, and having the same plan configuration as the first semiconductor region; a second gate electrode having the same cross-shaped plan configuration as the first gate electrode, formed on the second semiconductor region with a second gate insulating film interposed therebetween, and having an intersecting portion at which a third gate portion disposed in the X-axis direction and a fourth gate portion disposed in the Y-axis direction intersect each other; and a second impurity diffusion layer formed in an area of the second semiconductor region which is other than a portion thereof underlying the second gate electrode, partitioned by the second gate electrode into four diffusion regions, and having the same conductivity type as the first impurity diffusion layer, wherein the one of the four diffusion regions of the first impurity diffusion layer arranged in paired adjacent relation with the first gate portion interposed therebetween which is located on a negative side of the X-axis and on a positive side of the Y-axis and the one of the four diffusion regions of the second impurity diffusion layer arranged in paired adjacent relation with the third gate portion interposed therebetween which is located on the negative side of the X-axis and on a negative side of the Y-axis are connected to a source terminal and the one of the four diffusion regions of the first impurity diffusion layer arranged in paired adjacent relation with the first gate portion interposed therebetween which is located on a positive side of the X-axis and on the positive side of the Y-axis and the one of the four diffusion regions of the second impurity diffusion layer arranged in paired adjacent relation with the third gate portion interposed therebetween which is located on the positive side of the X-axis and on the negative side of the Y-axis are connected to drain terminals.

In the arrangement, when the electric characteristics of the two pairs of transistors each comprised of the first semiconductor region and of the first gate electrode having the cross-shaped plan configuration and placed at a displaced position on the first semiconductor region, a leakage current or the like occurs between the two pairs of transistors to degrade the accuracy of the electric characteristics. Thus, the semiconductor evaluation device according the present invention further comprises the second gate electrode and the second semiconductor region having the same plan configurations as the first gate electrode and the first semiconductor region. Accordingly, when the first and second gate electrodes are displaced by equal amounts in the positive direction of the Y-axis, e.g., measurement of the one transistor comprised of the diffusion regions of the first semiconductor region which are located on the positive side of the Y-axis with the second gate portion of the first gate electrode interposed therebetween and measurement of the one transistor comprised of the diffusion regions of the second semiconductor region which are located on the negative side of the Y-axis with the third gate portion of the second gate electrode interposed therebetween allows measurement equivalent to that when performed with respect to the two pairs of transistors as measurement targets which are comprised of the first semiconductor region and the first gate electrode to be performed without causing a problem of a leakage current or the like.

When the semiconductor evaluation device according to the present invention comprises the second gate electrode and the second impurity diffusion layer, the two of the four diffusion regions of the first impurity diffusion layer arranged in paired adjacent relation with the first gate portion interposed therebetween which are located on the negative side of the Y-axis and the two of the four diffusion regions of the second impurity diffusion layer arranged in paired adjacent relation with the third gate portion interposed therebetween which are located on the positive side of the Y-axis are preferably placed in an electrically floating state.

When the semiconductor evaluation device according to the present invention comprises the second gate electrode and the second impurity diffusion layer, the intersecting portions of the first and second gate electrodes preferably have respective center positions thereof displaced by equal amounts in the same direction from respective center positions of the first and second semiconductor regions.

When the semiconductor evaluation device according to the present invention comprises the second gate electrode and the second impurity diffusion layer, it preferably further comprises: logic circuits formed outside the semiconductor regions and electrically connected individually to each of the diffusion regions of the first impurity diffusion layer and to each of the diffusion regions of the second impurity diffusion layer each via a contact and a wire; and a plurality of measurement pads electrically connected to the individual logic circuits each via a wire.

A first evaluation method according to the present invention is an evaluation method for evaluating an amount of mask misalignment in an optical exposure step during fabrication of a semiconductor device by using a semiconductor evaluation device comprising: a gate electrode having a cross-shaped plan configuration, formed on a semiconductor region with a gate insulating film interposed therebetween, and having an intersecting portion at which a first gate portion disposed in an X-axis direction and a second gate portion disposed in a Y-axis direction intersect each other; and an impurity diffusion layer formed in an area of the semiconductor region which is other than a portion thereof underlying the gate electrode and partitioned by the gate electrode into four diffusion regions, the evaluation method comprising the steps of: (a) displacing a center position of the intersecting portion of the gate electrode from a center position of the semiconductor region by a first amount of displacement; (b) after the step (a), designating a transistor including the two of the four impurity diffusion regions of the impurity diffusion layer which are opposed to each other with the first gate portion or the second gate portion interposed therebetween as a first transistor, while designating a transistor including the other two diffusion regions as a second transistor, and individually measuring a fist electric characteristic of the first transistor and a second electric characteristic of the second transistor; (c) calculating a first difference between the first electric characteristic and the second electric characteristic; (d) after the step (b), displacing the center position of the intersecting portion of the gate electrode from the center position of the semiconductor region by a second amount of displacement; (e) after the step (d), designating a transistor including the two of the four impurity diffusion regions of the impurity diffusion layer which are opposed to each other with the first gate portion or the second gate portion interposed therebetween as a third transistor, while designating a transistor including the other two diffusion regions as a fourth transistor, and individually measuring a third electric characteristic of the third transistor and a fourth electric characteristic of the fourth transistor; (f) calculating a second difference between the third electric characteristic and the fourth electric characteristic; (g) deriving a relational expression for determining the actual amount of mask misalignment from the first difference, the first amount of displacement, the second difference, and the second amount of displacement; and (h) determining the actual amount of mask misalignment by using the relational expression.

In accordance with the first evaluation method, electric measurement is performed at least twice by setting the first amount of displacement and the second amount of displacement and the relational expression for determining the actual amount of mask misalignment is derived from the amounts of displacement and the difference between the measured electric characteristics. This allows prompt and high-accuracy evaluation of the amount of vertical misalignment and the amount of horizontal misalignment at an arbitrary position on a wafer or chip by using the same pattern.

A second evaluation method according to the present invention is an evaluation method for evaluating an amount of mask misalignment in an optical exposure step during fabrication of a semiconductor device by using a semiconductor evaluation device comprising: a gate electrode having a cross-shaped plan configuration, formed on a semiconductor region with a gate insulating film interposed therebetween, and having an intersecting portion at which a first gate portion disposed in an X-axis direction and a second gate portion disposed in a Y-axis direction intersect each other; and an impurity diffusion layer formed in an area of the semiconductor region which is other than a portion thereof underlying the gate electrode and partitioned by the gate electrode into four diffusion regions, the evaluation method comprising the steps of: (a) designating a transistor including the two of the four impurity diffusion regions of the impurity diffusion layer which are opposed to each other with the first gate portion or the second gate portion interposed therebetween as a first transistor, while designating a transistor including the other two diffusion regions as a second transistor, and deriving a relational expression for determining the actual amount of mask misalignment by simulating a first difference between a first electric characteristic of the first transistor and a second electric characteristic of the second transistor when the gate electrode is displaced by a specified amount; (b) after the step (a), designating a transistor including the two of the four impurity diffusion regions of the impurity diffusion layer which are opposed to each other with the first gate portion or the second gate portion interposed therebetween as a third transistor, while designating a transistor including the other two diffusion regions as a fourth transistor, and individually measuring the first electric characteristic of the third transistor and the second electric characteristic of the fourth transistor; (c) calculating a second difference between the first electric characteristic and the second electric characteristic; and (d) determining the actual amount of mask misalignment by applying the second difference to the relational expression.

In accordance with the second evaluation method, the relational expression for determining the actual amount of mask misalignment is preliminarily derived by simulating the first difference between the first electric characteristic of the first transistor and the second electric characteristic of the second transistor when the gate electrode has been displaced by the specified amount. Accordingly, the actual amount of mask misalignment can be easily determined by merely performing measurement (actual measurement) at least once and applying the second difference as the measured value to the relational expression.

Thus, the semiconductor evaluation device according to the present invention and the evaluation method using the semiconductor evaluation device allow prompt and high-accuracy electric evaluation of the amount of misalignment between a semiconductor region serving as the active region of a semiconductor device and a gate electrode at an arbitrary position on a wafer or chip. As a result, it is possible to perform defect analysis, monitor a fabrication process, and improve the degrees of perfection of a fabrication technology and design.

### BRIEF DESCRIPTION OF THE DRAWINGS

FIG. 1 is a plan view showing a semiconductor evaluation device according to a first embodiment of the present invention;

FIG. 2 is a flow chart of a method for evaluating an amount of mask misalignment using the semiconductor evaluation device according to the first embodiment;

FIG. 3 is a graph illustrating the method for evaluating an amount of mask misalignment using the semiconductor evaluation device according to the first embodiment;

FIG. 4 is a flow chart of a method for evaluating an amount of mask misalignment using a semiconductor evaluation device according to a second embodiment of the present invention;

FIG. 5 is a graph illustrating the method for evaluating an amount of mask misalignment using the semiconductor evaluation device according to the second embodiment; and

FIG. 6 is a circuit diagram and a partially enlarged plan view each showing a connection method for a semiconductor evaluation device according to a third embodiment of the present invention.

### DESCRIPTION OF THE PREFERRED EMBODIMENTS

### Embodiment 1

A semiconductor evaluation device according to a first embodiment of the present invention and an evaluation method using the semiconductor evaluation device will be described with reference to the drawings.

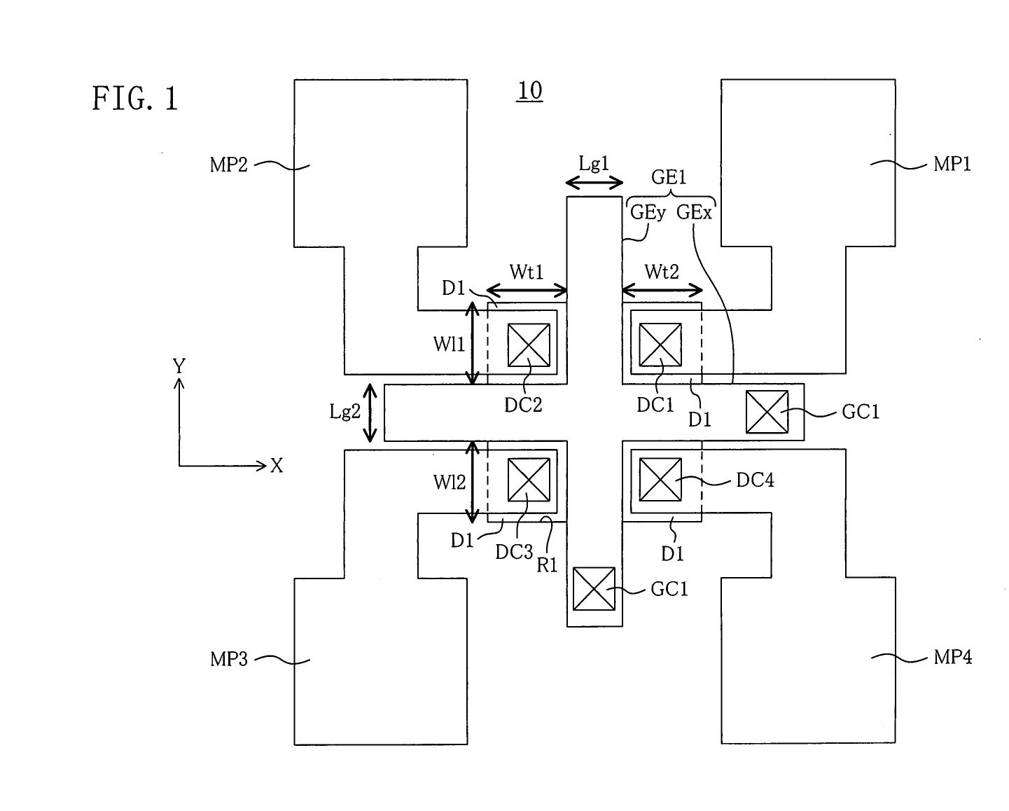

FIG. 1 shows a plan structure of the semiconductor evaluation device according to the first embodiment. As shown in FIG. 1, the semiconductor evaluation device according to the first embodiment is surrounded by an isolation region 10 selectively formed in an upper portion of a semiconductor substrate (not shown) made of, e.g., silicon (Si). The semiconductor evaluation device has: a semiconductor region R1 having a quadrilateral plan configuration, formed in the semiconductor substrate, and serving as an active region; a gate electrode GE1 having a cross-shaped plan configuration, formed on the semiconductor region R1 with a gate insulating film (not shown) interposed therebetween, and having an intersecting portion at which a first gate portion GEx disposed in the X-axis direction and a second gate portion GEy disposed in the Y-axis direction intersect each other; and an impurity diffusion layer D1 formed in the area (located laterally of the gate electrode GE1) of the semiconductor region R1 which is other than the portion thereof underlying the gate electrode GE1 and comprised of four diffusion regions serving as source/drain regions. It is to be noted that the plan configuration of the semiconductor region R1 need not necessarily be limited to a quadrilateral configuration.

In FIG. 1, four MISFETs are formed. For example, the gate width and gate length of the MISFET located on the positive side of the Y-axis with respect to the first gate portion GEx are (Wl1, Lg1) and the gate width and gate length of the MISFET located on the negative side of the Y-axis with respect to the first gate portion GEx are (Wl2, Lg1). On the other hand, the gate width and gate length of the MISFET located on the positive side of the X-axis with respect to the second gate portion GEy are (Wt2, Lg2) and the gate width and gate length of the MISFET located on the negative side of the X-axis the second gate portion GEy are (Wt1, Lg2).

The gate electrode GE1 has gate contacts GC1 formed at the respective end portions of the first and second gate portions GEx and GEy, each of which is connected to a metal pad via a metal wire not shown. At the time of measurement, a gate voltage is applied to each of the gate contacts GC1 from an external measurement apparatus via the metal pad and the metal wire. The gate contact GC1 may also be provided only on either one of the first and second gate portions GEx and GEy.

Contacts DC1, DC2, DC3, and DC4 are formed on the respective impurity diffusion regions of the impurity diffusion layer D1 which serve as the source/drain regions. The contacts DC1 to DC4 are connected individually to metal pads MP1, MP2, MP3, and MP4 by metal wires. A source voltage or a drain voltage is applied to each of the metal pads MP1 to MP4 or, alternatively, each of the metal pads MP1 to MP4 is placed in an electrically unconnected floating state.

In the first embodiment, n (n is an integer of 2 or more) semiconductor evaluation device are prepared by stepwise displacing the gate electrode GE1 in the semiconductor evaluation device having a gate pattern as shown in FIG. 1 n times, each time by a different amount ΔW of displacement, from the center position of the semiconductor region R1 in the X-axis direction, in the Y-axis, or in an oblique direction synthesized from the X-axis and the Y-axis directions. For example, fifteen patterns are prepared by displacing the gate electrode GE1 in increments or decrements of 10 nm over the range of −70 nm to 70 nm (ΔW=−70 nm to 70 nm). At this time, when it is assumed that W=Wl1 and Wl2 is satisfied, the respective transistor sizes (gate widths, gate lengths) of the patterns become (W/2+ΔW, Lg1), (W/2−ΔW, Lg1), (Wt2, Lg2), and (Wt1, Lg2).

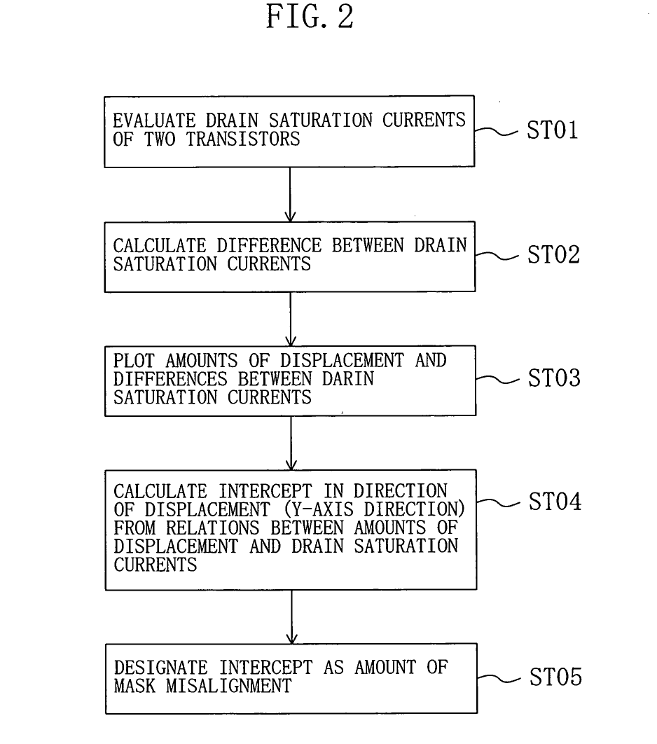

A description will be given herein below to an evaluation method using the plurality of semiconductor evaluation device having the patterns in which the gate electrode GE1 described above has been displaced in fifteen different ways with reference to the flow chart of FIG. 2.

First, as shown in Step ST01 of FIG. 2, when the amount of misalignment in the Y-axis direction is evaluated, the two transistors opposed to each other with the first gate portion GEx interposed therebetween, i.e., the first and second transistors having the transistor sizes of (W/2+ΔW, Lg1) and (W/2−ΔW, Lg1) are measured. When the first transistor having the transistor sizes of (W/2+ΔW, Lg1) is measured, the metal pad MP1 is connected to a source terminal (or to a drain terminal) and the metal pad MP2 is connected to the drain terminal (or to the source terminal). At this time, the metal pad MP4 is placed at the same potential as the metal pad MP1 or in the floating state and the metal pad MP3 is placed at the same potential as the metal pad MP2 or in the floating state. When the second transistor having the transistor sizes of (W/2−ΔW, Lg1) is measured also, the same connections as provided for the first transistor are provided.

The drain saturation current of each of the transistors is represented by the following numerical expressions:

Idsat(W/2+ΔW)=idsat·W/2+idsat·ΔW+δ (1)

Idsat(W/2−ΔW)=idsat·W/2−idsat·ΔW+δ (2)

wherein the left sides are functions of the gate width W, idsat represents a drain saturation current per unit gate width, and each of δ, δ′ represents an extremely small current flowing in the area of the semiconductor region R1 which is located under the intersecting portion of the gate electrode GE1.

Next, as shown in Step ST02, the difference between the drain saturation currents represented by the numerical expressions (1) and (2) is calculated to increase the sensitivity of each of the drain saturation currents related to ΔW, which is represented by the following numerical expression (3):

$$\begin{matrix}Δ Idsat ( Δ W ) = Idsat ( W / 2 + Δ W ) - Idsat ( W / 2 - Δ W ) \\ \approx 2 idsat \cdot Δ W\end{matrix} \qquad ( 3 )$$

wherein the difference (δ−δ′) between the extremely small currents is approximated to 0.

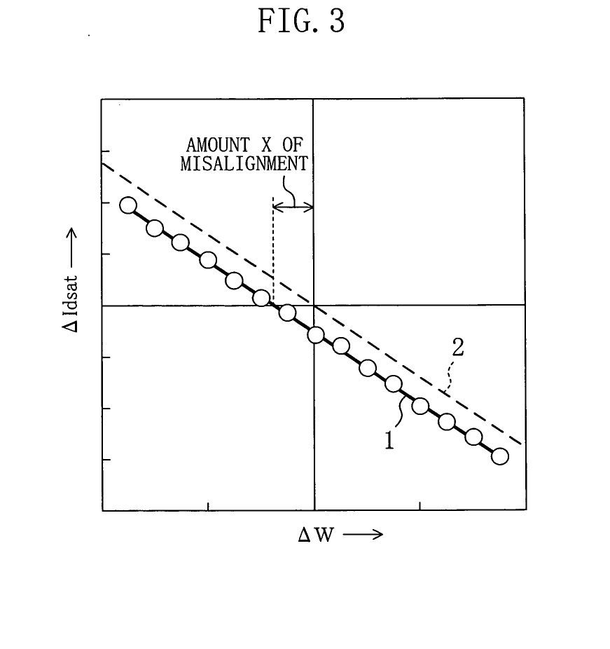

Next, as shown in Step ST03 and FIG. 3, fifteen amounts ΔW of displacement and the fifteen differences ΔIdsat between the drain saturation currents are plotted.

Judging from the numerical expression (3), if the amount of mask misalignment is zero, ΔIdsat=0 should be satisfied when ΔW=0 is satisfied. However, since misalignment occurs in an actual fabrication process, i.e., since misalignment occurs when a mask having a design pattern for the semiconductor region R1 serving as the active region surrounded by the isolation region 10 is aligned with another mask having a design pattern for the gate electrode GE1, the straight line 1 representing actually measured values given by ΔIdsat and ΔW does not pass through the origin, as shown in FIG. 3. The displacement from the origin, i.e., the ΔW-axis intercept of the straight line defined by ΔIdsat and ΔW represents the amount of misalignment. The broken line 2 shown in FIG. 3 represents design values for ΔIdsat and ΔW.

Although the first embodiment has used the drain saturation currents Idsat as the electric characteristics of the transistors, the electric characteristics of the transistors need not be limited to the drain saturation currents. Misalignment can also be evaluated even when drain currents in linear regions and other electric characteristics are used.

Next, as shown in Step ST04, the intercept (X-axis intercept of FIG. 3) in the direction of displacement (Y-axis direction of FIG. 1) is calculated from the relationship between the amount ΔW of displacement of the gate electrode GE1 and the difference ΔIdsat between the drain saturation currents.

If it is assumed that the relationship represented by ΔIdsat=A·ΔW+B (wherein A and B are constants) is satisfied, the amount X of mask misalignment can be determined from the following numerical expression (4):

Amount X of Misalignment=−B/A (4).

Next, as shown in Step ST05, it is assumed that the X-axis intercept of FIG. 3 is designated as the amount of misalignment.

Thus, in the first embodiment, the amount of mask misalignment can be evaluated from the correlations between the amounts of displacement of the single gate electrode GE1 and the differences between the electric characteristics of the four MISFETs by preparing the plurality of evaluation patterns in each of which the gate electrode GE1 having the cross-shaped plan configuration is displaced from the center position of the semiconductor region R1 by a different amount of displacement.

In addition, the use of the gate pattern having the cross-shaped plan configuration for the gate electrode GE1 allows simultaneous evaluation of the amounts of mask misalignment in the X-axis direction and in the Y-axis direction.

The accuracy of measuring the amount X of mask misalignment will be estimated therein below. A standard deviation δΔIdsat showing variations in each ΔIdsat due to impurity fluctuations is represented by the following numerical expression (5):

δΔIdsat=√2·P/√(Lg·W) (5)

wherein P is the Pelgrom coefficient of a saturation current (see, e.g., IEEE J. Solid-State Circuits, Vol. 24, pp. 1433-1440 (1989)).

The standard deviation δx of the ΔW-axis intercept of the regression line ΔIdsat=A·ΔW+B is given by the following numerical expression (6):

δx²=δA²/B²+A²·δB²/B⁴ (6)

wherein δA and δB are the respective standard deviations of the gradient A and the intercept B, which can be represented by the following numerical expressions (7), (8), and (9) (see, e.g., “Data Reduction and Error Analysis,” McGraw-Hill, pp. 109-110, (2003)):

δA=δΔIdsat·√(Σx²/Δ) (7)

δB=δΔIdsat·√(N/Δ) (8)

Δ=N·Σx²−(Σx)² (9)

wherein N is the number of data pairs (ΔW, ΔIdsat) used to determine the regression line. The use of the numerical expressions shown above can achieve a measurement accuracy of 3 nm with 3δ when, e.g., transistors each satisfying W/Lg=1/0.7 μm are used.

Although the number N of data pairs has been assumed to be 15 in the first embodiment, it is not limited thereto. For example, it is sufficient for the number N of data pairs to be 2 or more and preferably 3 or more.

In Document 1 described above, the use of transistors each satisfying W/Lg=0.8/2.4 μm and a measurement accuracy of 6.5 nm 3δ are reported. In addition, since no consideration has been given to variations in the drain saturation current Idsat due to impurity fluctuations, it is expected that an error is not less than the reported value. Moreover, in the evaluation method disclosed in Document 1, the evaluation pattern in the vertical (Y-axis) direction is different from the evaluation pattern in the horizontal (X-axis) direction. As a result, there is a possibility that the electric characteristics of the evaluation pattern in the vertical direction are undesirably different from those of the evaluation pattern in the horizontal direction under the influence of a stress, an optical proximity effect, or the like

### Embodiment 2

A second embodiment of the present invention will be described herein below with reference to the drawings.

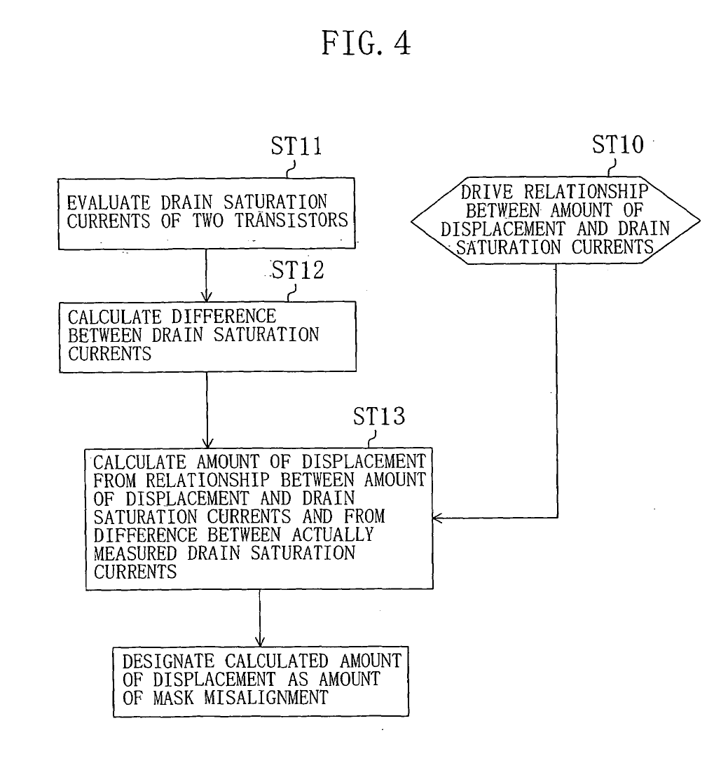

FIG. 4 shows a flow chart of an evaluation method using a semiconductor evaluation device according to the second embodiment.

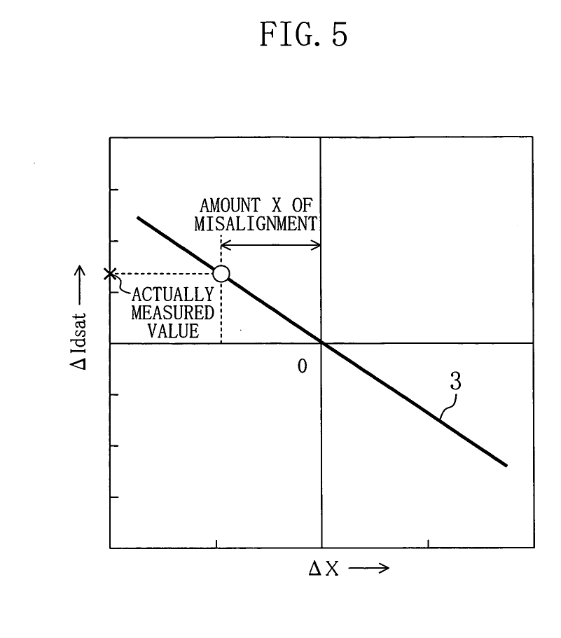

First, in Step ST10 shown in FIG. 4, the relationship (given by the straight line 3) between an actual amount X of misalignment (at the completion of fabrication) shown in FIG. 5 and the difference ΔIdsat between drain saturation currents is derived.

In the second embodiment, the relationship between the actual amount X of misalignment and the difference ΔIdsat between drain saturation currents is derived in a tabular form (as a table) or as a function. Specifically, in the semiconductor evaluation device shown in FIG. 1, the difference ΔIdsat between the drain saturation currents of transistors obtained by varying the gate width (e.g., Wl1) is determined by using a known TEG, device simulator, or circuit simulator.

Next, in Step ST11 shown in FIG. 4, the semiconductor evaluation device shown in FIG. 1 is formed to have design values and the drain saturation currents of one pair of opposing transistors selected among the formed four transistors are measured by the same method as used in the first embodiment.

Next, in Step ST12, the difference ΔIdsat between the drain saturation currents of the pair of measured transistors is calculated.

Next, in Step ST13, an amount of mask misalignment can be determined from the preliminarily derived function shown in FIG. 5, i.e., from the relationship (given by the straight line 3) between the amount X of mask misalignment and the difference ΔIdsat between the drain saturation currents, which has been obtained by simulation or the like, and from the difference ΔIdsat between the actually measured drain saturation currents.

Thus, according to the second embodiment, the amount of misalignment of the mask for the gate electrode GE1 can be easily evaluated by, e.g., preliminarily calculating the relationship between the amount of mask displacement between the pair of transistors and the difference between the drain saturation currents as an exemplary electric characteristic by simulation or the like and then performing actual measurement at least once afterwards.

Moreover, since the second embodiment has used the gate pattern having the cross-shaped plan configuration for the gate electrode GE1 composing each of the MISFETs in the semiconductor evaluation device, mask misalignment in the X-axis direction and mask misalignment in the Y-axis direction can be evaluated simultaneously.

Although the evaluation method is easier in the second embodiment than in the first embodiment, the accuracy of evaluation is higher in the first embodiment.

### Embodiment 3

A third embodiment of the present invention will be described herein below with reference to the drawings.

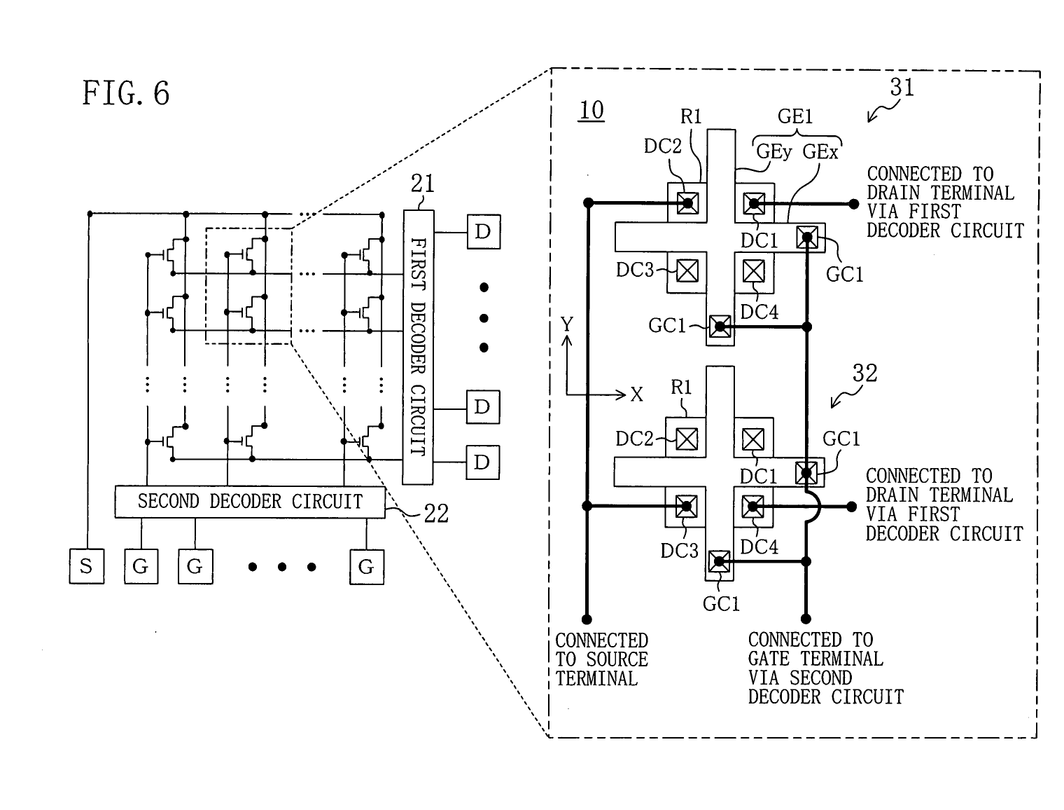

FIG. 6 shows an embodiment of connection in a semiconductor evaluation device according to the third embodiment. The description of components shown in FIG. 6 which are the same as those shown in FIG. 1 will be omitted by retaining the same reference numerals. As shown in the circuit diagram of FIG. 6, the third embodiment has formed a plurality of the semiconductor evaluation device shown in FIG. 1 in, e.g., rows and columns on a semiconductor substrate. The semiconductor evaluation device are connected individually to drain terminal D each via a first decoder circuit 21 and are connected to individual gate terminals G each via a second decoder circuit 22.

More specifically, in the first and second semiconductor evaluation device 31 and 32 shown in the partially enlarged view of FIG. 6, each of the gate contacts GC1 is connected to the corresponding one of the gate terminals G via the second decoder circuit 22.

The contact DC1 on the impurity diffusion layer D1 in the first semiconductor evaluation device 31 and the contact DC4 on the impurity diffusion layer D1 in the second semiconductor evaluation device 32 are connected to the individual drain terminals D via the first decoder circuit 21.

The contact DC2 on the impurity diffusion layer D1 in the first semiconductor evaluation device 31 and the contact DC3 on the impurity diffusion layer D1 in the second semiconductor evaluation device 32 are connected to a source terminal S.

In the case of using the evaluation method according to the first embodiment, the amounts of displacing the respective gate electrodes GE1 of the first and second semiconductor evaluation device 31 and 32 for obtaining a plurality of data pairs (ΔW, ΔIdsat) are set to the same values.

As a result, measurement equivalent to that when performed with respect to one pair of MISFETs included in the first semiconductor evaluation device 31 can be performed by using one MISFET in the first semiconductor evaluation device 31 and one MISFET in the second semiconductor evaluation device 32 without causing the problem of a leakage current or the like.

By further using so-called on-chip logic circuits integrated on a semiconductor substrate, such as the first and second decoder circuits 21 and 22, it is possible to improve the integration density of the plurality of semiconductor evaluation device and reduce a measurement time.

By forming the plurality of semiconductor evaluation device each having the same patterns and averaging the electric characteristics of the individual MISFETs, it is possible to further improve the accuracy of evaluating the amount of mask misalignment by reducing measurement variations.

Thus, the semiconductor evaluation device according to the present invention and the evaluation method using the same allow prompt and high-accuracy electric evaluation of an amount of misalignment between the active region of a transistor and a gate electrode at an arbitrary position on a wafer (chip) and are therefore useful for a semiconductor evaluation device for electrically evaluating an amount of mask misalignment in process steps for fabricating a semiconductor device or the like.

What is claimed is:

1. A semiconductor evaluation device for evaluating an amount of mask misalignment in an optical exposure step during fabrication of a semiconductor device, the device comprising:
a first semiconductor region selectively formed in a semiconductor substrate;
a first gate electrode having a cross-shaped plan configuration, formed on the first semiconductor region with a first gate insulating film interposed therebetween, and having an intersecting portion at which a first gate portion disposed in an X-axis direction and a second gate portion disposed in a Y-axis direction intersect each other; and
a first impurity diffusion layer formed in an area of the first semiconductor region which is other than a portion thereof underlying the first gate electrode and partitioned by the first gate electrode into four diffusion regions.

2. The semiconductor evaluation device of claim 1, further comprising:
a plurality of measurement pads formed outside the first semiconductor region and electrically connected to the individual diffusion regions of the first impurity diffusion layer each via a contact and a wire.

3. The semiconductor evaluation device of claim 1, wherein
the two of the diffusion regions of the first impurity diffusion layer which are adjacent to each other with the first gate portion interposed therebetween and located on a positive side of the Y-axis are connected to a source terminal and
the two of the diffusion regions of the first impurity diffusion layer which are adjacent to each other with the first gate portion interposed therebetween and located on a negative side of the Y-axis are connected to a drain terminal.

4. The semiconductor evaluation device of claim 1, wherein the intersecting portion of the first gate electrode has a center position thereof displaced from a center position of the first semiconductor region.

5. The semiconductor evaluation device of claim 1, further comprising:
a second semiconductor region formed on the semiconductor substrate, isolated from the first semiconductor region by an isolation region, and having the same plan configuration as the first semiconductor region;
a second gate electrode having the same cross-shaped plan configuration as the first gate electrode, formed on the second semiconductor region with a second gate insulating film interposed therebetween, and having an intersecting portion at which a third gate portion disposed in the X-axis direction and a fourth gate portion disposed in the Y-axis direction intersect each other; and
a second impurity diffuision layer formed in an area of the second semiconductor region which is other than a portion thereof underlying the second gate electrode, partitioned by the second gate electrode into four diffusion regions, and having the same conductivity type as the first impurity diffusion layer, wherein
the one of the four diffusion regions of the first impurity diffusion layer arranged in paired adjacent relation with the first gate portion interposed therebetween which is located on a negative side of the X-axis and on a positive side of the Y-axis and the one of the four diffusion regions of the second impurity diffusion layer arranged in paired adjacent relation with the third gate portion interposed therebetween which is located on the negative side of the X-axis and on a negative side of the Y-axis are connected to a source terminal and
the one of the four diffusion regions of the first impurity diffusion layer arranged in paired adjacent relation with the first gate portion interposed therebetween which is located on a positive side of the X-axis and on the positive side of the Y-axis and the one of the four diffusion regions of the second impurity diffusion layer arranged in paired adjacent relation with the third gate portion interposed therebetween which is located on the positive side of the X-axis and on the negative side of the Y-axis are connected to drain terminals.

6. The semiconductor evaluation device of claim 5, wherein the two of the four diffusion regions of the first impurity diffusion layer arranged in paired adjacent relation with the first gate portion interposed therebetween which are located on the negative side of the Y-axis and the two of the four diffusion regions of the second impurity diffusion layer arranged in paired adjacent relation with the third gate portion interposed therebetween which are located on the positive side of the Y-axis are placed in an electrically floating state.

7. The semiconductor evaluation device of claim 5, wherein the intersecting portions of the first and second gate electrodes have respective center positions thereof displaced by equal amounts in the same direction from respective center positions of the first and second semiconductor regions.

8. The semiconductor evaluation device of claim 5, further comprising:
logic circuits formed outside the semiconductor regions and electrically connected individually to each of the diffusion regions of the first impurity diffusion layer and to each of the diffusion regions of the second impurity diffusion layer each via a contact and a wire; and
a plurality of measurement pads electrically connected to the individual logic circuits each via a wire.

9. An evaluation method for evaluating an amount of mask misalignment in an optical exposure step during fabrication of a semiconductor device by using a semiconductor evaluation device comprising: a gate electrode having a cross-shaped plan configuration, formed on a semiconductor region with a gate insulating film interposed therebetween, and having an intersecting portion at which a first gate portion disposed in an X-axis direction and a second gate portion disposed in a Y-axis direction intersect each other; and an impurity diffusion layer formed in an area of the semiconductor region which is other than a portion thereof underlying the gate electrode and partitioned by the gate electrode into four diffusion regions, the evaluation method comprising the steps of:
(a) displacing a center position of the intersecting portion of the gate electrode from a center position of the semiconductor region by a first amount of displacement;
(b) after the step (a), designating a transistor including the two of the four impurity diffusion regions of the impurity diffusion layer which are opposed to each other with the first gate portion or the second gate portion interposed therebetween as a first transistor, while designating a transistor including the other two diffusion regions as a second transistor, and individually measuring a fist electric characteristic of the first transistor and a second electric characteristic of the second transistor;
(c) calculating a first difference between the first electric characteristic and the second electric characteristic;
(d) after the step (b), displacing the center position of the intersecting portion of the gate electrode from the center position of the semiconductor region by a second amount of displacement;
(e) after the step (d), designating a transistor including the two of the four impurity diffusion regions of the impurity diffusion layer which are opposed to each other with the first gate portion or the second gate portion interposed therebetween as a third transistor, while designating a transistor including the other two diffusion regions as a fourth transistor, and individually measuring a third electric characteristic of the third transistor and a fourth electric characteristic of the fourth transistor;
(f) calculating a second difference between the third electric characteristic and the fourth electric characteristic;
(g) deriving a relational expression for determining the actual amount of mask misalignment from the first difference, the first amount of displacement, the second difference, and the second amount of displacement; and
(h) determining the actual amount of mask misalignment by using the relational expression.

10. An evaluation method for evaluating an amount of mask misalignment in an optical exposure step during fabrication of a semiconductor device by using a semiconductor evaluation device comprising: a gate electrode having a cross-shaped plan configuration, formed on a semiconductor region with a gate insulating film interposed therebetween, and having an intersecting portion at which a first gate portion disposed in an X-axis direction and a second gate portion disposed in a Y-axis direction intersect each other; and an impurity diffusion layer formed in an area of the semiconductor region which is other than a portion thereof underlying the gate electrode and partitioned by the gate electrode into four diffusion regions, the evaluation method comprising the steps of:
(a) designating a transistor including the two of the four impurity diffusion regions of the impurity diffusion layer which are opposed to each other with the first gate portion or the second gate portion interposed therebetween as a first transistor, while designating a transistor including the other two diffusion regions as a second transistor, and deriving a relational expression for determining the actual amount of mask misalignment by simulating a first difference between a first electric characteristic of the first transistor and a second electric characteristic of the second transistor when the gate electrode is displaced by a specified amount;
(b) after the step (a), designating a transistor including the two of the four impurity diffusion regions of the impurity diffusion layer which are opposed to each other with the first gate portion or the second gate portion interposed therebetween as a third transistor, while designating a transistor including the other two diffusion regions as a fourth transistor, and individually measuring the first electric characteristic of the third transistor and the second electric characteristic of the fourth transistor;
(c) calculating a second difference between the first electric characteristic and the second electric characteristic; and
(d) determining the actual amount of mask misalignment by applying the second difference to the relational expression.
